(19) United States
(12) Patent Application Publication
(10) Pub. No.: US 2026/0122889 A1
(43) Pub. Date: Apr. 30, 2026

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventors: Mi Seong PARK, Icheon-si Gyeonggi-do (KR); Jung Shik JANG, Icheon-si Gyeonggi-do (KR); Rho Gyu KWAK, Icheon-si Gyeonggi-do (KR); In Su PARK, Icheon-si Gyeonggi-do (KR); Na Yeong YANG, Icheon-si Gyeonggi-do (KR); Seok Min CHOI, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 19/208,364

(22) Filed: May 14, 2025

(30) Foreign Application Priority Data
Oct. 31, 2024 (KR) 10-2024-0152997

(51) Int. Cl. H10B 41/10; H10B 41/27; H10B 41/35; H10B 43/10; H10B 43/27; H10B 43/35; H10D 30/01; H10D 30/68; H10D 30/69

(52) U.S. Cl. CPC H10B 41/10; H10B 41/27; H10B 41/35; H10B 43/10; H10B 43/27; H10B 43/35; H10D 30/0411; H10D 30/0413; H10D 30/689; H10D 30/693; H10D 30/697

(57) ABSTRACT

A semiconductor memory device and a method of manufacturing the semiconductor memory device are provided. The semiconductor memory device includes a cell pillar structure and a conductive layer surrounding the external surface of the cell pillar structure. Portions of the external surface of the cell pillar structure are arranged at different distances from a center point on a plurality of first axes and a plurality of second axes radially extending from the center point. The plurality of first axes and the plurality of second axes are alternately arranged in a clockwise direction, and the cell pillar structure includes a plurality of channel portions and an isolation structure extending between the plurality of channel portions from the center point.

### CROSS-REFERENCE TO RELATED APPLICATION

The present application claims priority under 35 U.S.C. § 119 (a) to Korean patent application number 10-2024-0152997 filed on Oct. 31, 2024, in the Korean Intellectual Property Office, the entire disclosure of which application is incorporated by reference herein.

### BACKGROUND

### 1. Technical Field

Various embodiments of the present disclosure generally relate to a semiconductor memory device, and more particularly, to a semiconductor memory device including a three-dimensional memory cell array and a method of manufacturing the semiconductor memory device.

### 2. Related Art

Semiconductor memory devices are applicable not only to small electronic devices, but also to electronic systems in various fields such as automobiles, medical care, and data centers. As a result, the demand for semiconductor memory devices is increasing.

A semiconductor memory device includes a memory cell array, and the memory cell array includes a plurality of memory cells for data storage. Semiconductor memory devices are divided into two-dimensional semiconductor memory devices including two-dimensional memory cell arrays and three-dimensional semiconductor memory devices including three-dimensional memory cell arrays.

A plurality of memory cells of a three-dimensional memory cell array are arranged in an X-axis direction, a Y-axis direction, and a Z-axis direction. A plurality of memory cells of a two-dimensional memory cell array are arranged in the X-axis direction and the Y-axis direction. Due to this structural difference, the three-dimensional memory cell array is more advantageous for increasing the capacity of a semiconductor memory device as compared to the two-dimensional memory cell array.

The plurality of memory cells of the three-dimensional memory cell array may be divided into a plurality of memory cell strings corresponding to a plurality of cell pillar structures. Each cell pillar structure includes a channel layer. The memory cells included in each memory cell string may be coupled in series by the channel layer. In order to improve the degree of integration of the memory cell strings, the channel layer of the cell pillar structure may be divided into two or more channel portions. However, this may result in deterioration of operation reliability of the memory cell string.

### SUMMARY

According to an embodiment, a semiconductor memory device may include a cell pillar structure including an external surface crossing a plurality of first axes and a plurality of second axes, the plurality of first axes and the plurality of second axes radially extending from a center point in a first plane, the plurality of first axes alternately arranged in a clockwise direction with the plurality of second axes, the external surface of the cell pillar structure spaced apart from the center point, the cell pillar structure extending in a stacking direction crossing the first plane and a plurality of conductive layers spaced apart from each other in the stacking direction and surrounding the external surface of the cell pillar structure. The cell pillar structure may include a plurality of channel portions crossing the plurality of first axes, respectively, each of the plurality of channel portions including a radius of curvature defined between the center point and a vertex crossing a corresponding first axis among the plurality of first axes, a plurality of memory portions disposed between each of the plurality of conductive layers and the plurality of channel portions, and an isolation structure disposed between the plurality of channel portions and extending toward the center point. Each of the plurality of channel portions may include an end disposed at a first distance of 30% to 80% with respect to the radius of curvature from the vertex in an extending direction of the corresponding first axis.

According to an embodiment, a method of manufacturing a semiconductor memory device may include forming a stack including a plurality of material layers extending in a first plane and arranged in a stacking direction crossing the first plane, forming, by etching the stack, a hole including a first inner wall crossing a plurality of first axes and a plurality of second axes, the plurality of first axes and the plurality of second axes radially extending from a center point in the first plane and alternately arranged in a clockwise direction, the first inner wall spaced apart from the center point, forming a channel layer extending on the first inner wall and including a second inner wall facing the center point, forming a plurality of seed barrier patterns extending on the second inner wall and arranged alternately with the plurality of second axes in the clockwise direction, selectively growing a plurality of growth barrier patterns from a plurality of third inner walls of the plurality of seed barrier patterns toward the center point to open a plurality of etching targets of the channel layer crossing the plurality of second axes, and forming a plurality of openings by removing the plurality of etching targets to penetrate the channel layer.

### BRIEF DESCRIPTION OF THE DRAWINGS

FIG. 1 is a circuit diagram illustrating a memory cell array of a semiconductor memory device according to an embodiment of the present disclosure;

FIGS. 2A and 2B are diagrams illustrating a semiconductor memory device according to embodiments of the present disclosure;

FIG. 3 is a diagram illustrating a gate stack and a cell pillar structure according to an embodiment of the present disclosure;

FIGS. 4A, 4B, and 4C are cross-sectional views illustrating a doped semiconductor structure and a cell pillar structure according to embodiments of the present disclosure;

FIGS. 5A, 5B, 6A and 6B are plan views showing a cross-section of a cell pillar structure according to embodiments of the present disclosure;

FIGS. 7A and 7B are a cross-sectional view and a plan view illustrating a stack, a hole, and layers disposed in the hole according to an embodiment of the present disclosure;

FIGS. 8A and 8B are plan views illustrating seed barrier patterns according to an embodiment of the present disclosure;

FIGS. 9A, 9B, 9C, 9D, 9E, and 9F are plan views illustrating growth barrier patterns, buffer patterns, channel portions, and memory portions according to an embodiment of the present disclosure;

FIGS. 10A and 10B are a cross-sectional view and a plan view showing a gate stack according to an embodiment of the present disclosure;

FIG. 11 is a plan view showing seed barrier patterns according to an embodiment of the present disclosure;

FIGS. 12A and 12B are a cross-sectional view and a plan view showing a stack, a hole, and layers disposed in the hole according to an embodiment of the present disclosure;

FIGS. 13A, 13B, and 13C are plan views illustrating channel portions, memory portions, and a conductive layer according to an embodiment of the present disclosure;

FIGS. 14A and 14B are a cross-sectional view and a plan view showing a stack, a hole, and layers disposed in the hole according to an embodiment of the present disclosure;

FIGS. 15A, 15B, and 15C are plan views showing channel portions and openings according to an embodiment of the present disclosure;

FIG. 16 is a plan view showing a stack, a hole, and layers disposed in the hole according to an embodiment of the present disclosure; and

FIG. 17 is a block diagram illustrating an electronic system according to an embodiment of the present disclosure.

### DETAILED DESCRIPTION

Specific structural or functional descriptions of examples of embodiments in accordance with concepts which are disclosed in this specification are illustrated only to describe the examples of embodiments in accordance with the concepts and the examples of embodiments in accordance with the concepts may be carried out by various forms but the descriptions are not limited to the examples of embodiments described in this specification.

Terms such as “first,” “second,” etc., are used to distinguish between various elements and do not imply size, order, priority, quantity, or importance of the elements. For example, a first element may be named as a second element in one example, and the second element may be named as a first element in another example. Terms such as “top,” “over,” “on,” “sidewall,” “upper,” “lower,” “inner,” “outer” and other terms implying relative spatial relationship or orientation are utilized only for the purpose of ease of description or reference to a drawing and are not otherwise limiting. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. The cross-hatching throughout the figures illustrates corresponding or similar areas between the figures rather than indicating the materials associated with the areas.

According to various embodiments of the present disclosure, a semiconductor memory device improving a degree of integration and operation reliability of a memory cell string and a method of manufacturing the semiconductor memory device are provided.

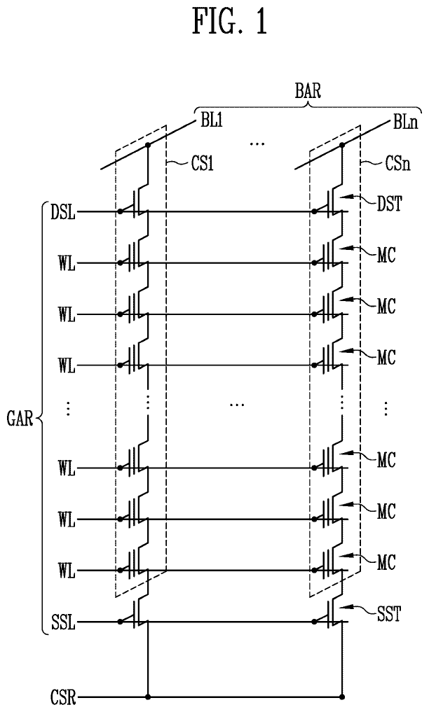

FIG. 1 is a circuit diagram illustrating a memory cell array of a semiconductor memory device according to an embodiment of the present disclosure.

Referring to FIG. 1, a memory cell array of a semiconductor memory device includes a plurality of memory cell strings CS1 to CSn, where n is a natural number equal to or greater than 2. The plurality of memory cell strings CS1 to CSn are coupled to a gate array GAR, a bit line array BAR, and a common source layer CSR.

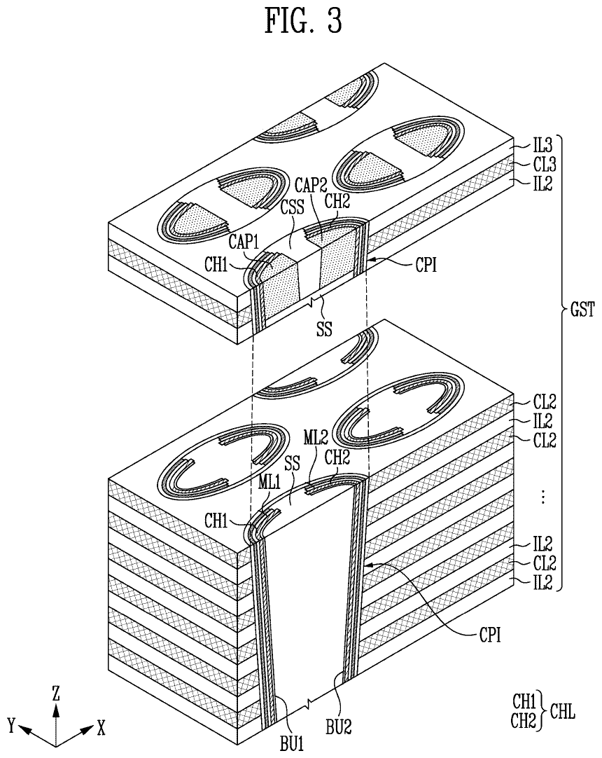

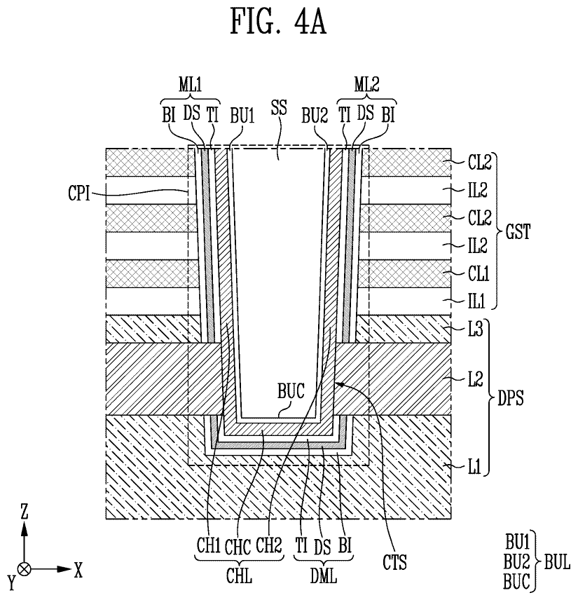

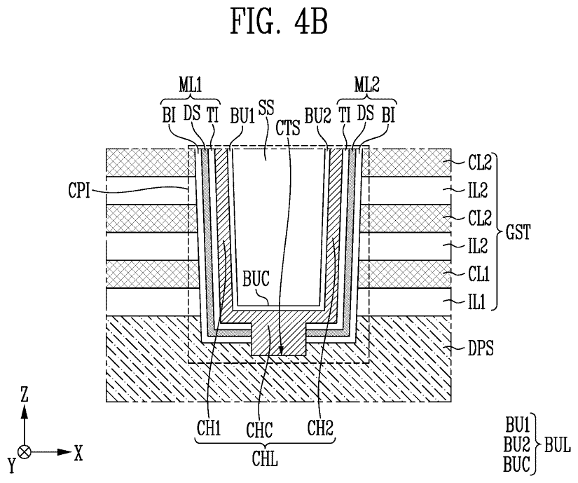

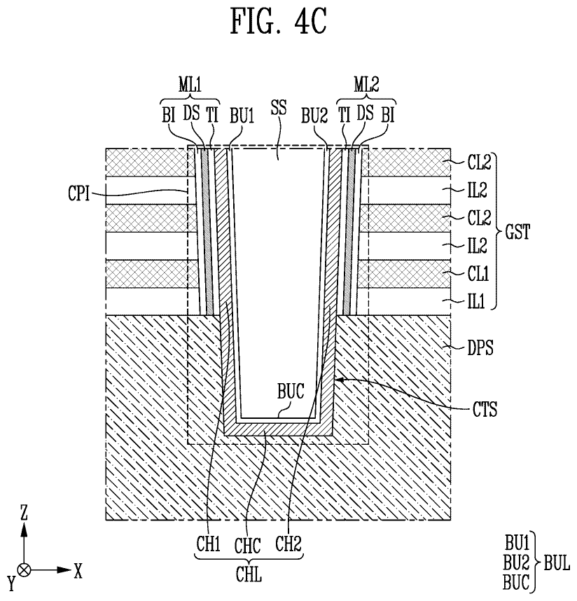

Each of the plurality of memory cell strings CS1 to CSn includes at least one source select transistor SST, a plurality of memory cells MC, and at least one drain select transistor DST. The plurality of memory cells MC are stacked between the source select transistor SST and the drain select transistor DST. The source select transistor SST, the plurality of memory cells MC, and the drain select transistor DST are coupled in series through a corresponding channel portion (e.g., CH1 or CH2 as shown in FIG. 3). A plurality of channel portions of the plurality of memory cell strings CS1 to CSn may be formed by partitioning a channel layer through an isolation structure. A cell pillar structure includes the channel layer. As an embodiment, referring to FIGS. 3, 4A, 4B, and 4C, a channel layer CHL of a cell pillar structure CPI may be divided into a first channel portion CH1 of the first memory cell string and a second channel portion CH2 of the second memory cell string by the isolation structure SS.

The gate array GAR includes a source select line SSL, a plurality of word lines WL, and a drain select line DSL. The source select line SSL may serve as the gate electrode of the source select transistor SST, each word line WL may serve as a gate electrode of the corresponding memory cell MC, and the drain select line DSL may serve as a gate electrode of the drain select transistor DST.

The bit line array BAR includes a plurality of bit lines BL1 to BLn, where n is a natural number of 2 or more. The plurality of bit lines BL1 to BLn correspond to the plurality of memory cell strings CS1 to CSn, respectively. Each of the plurality of bit lines BL1 to BLn is coupled to a channel portion of a corresponding memory cell string to selectively control the channel portion of the corresponding memory cell string. A voltage for precharging the channel portion corresponding to each of the plurality of bit lines BL1 to BLn may be applied to each of the plurality of bit lines BL1 to BLn.

The plurality of memory cell strings CS1 to CSn are coupled in parallel to the common source layer CSR. A voltage for discharging a plurality of channel portions of the plurality of memory cell strings CS1 to CSn may be applied to the common source layer CSR.

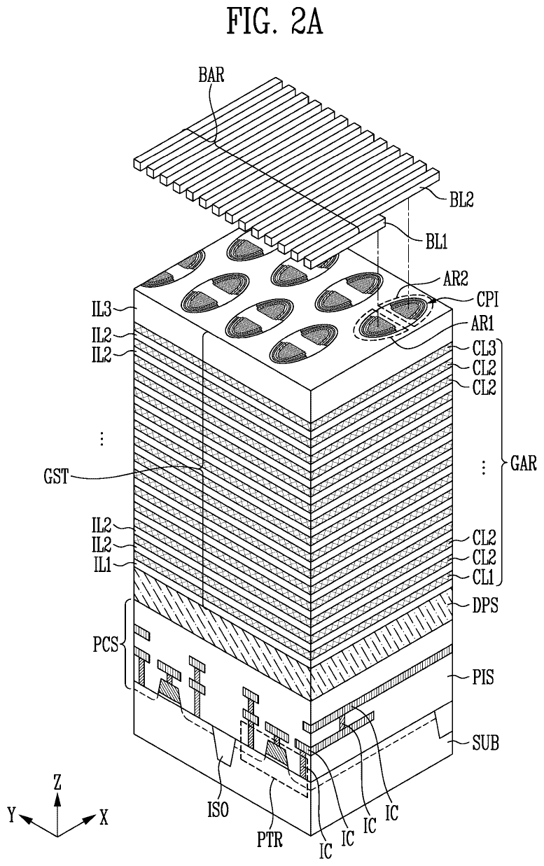

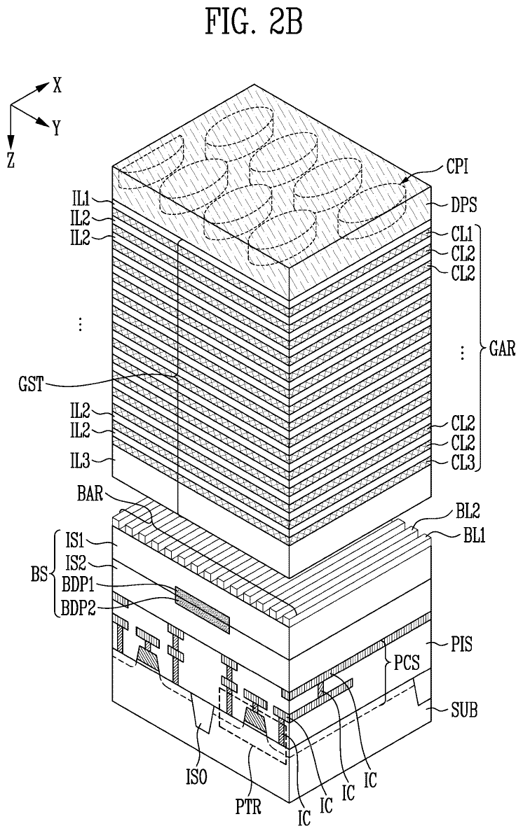

FIGS. 2A and 2B are diagrams illustrating a semiconductor memory device according to embodiments of the present disclosure.

Referring to FIGS. 2A and 2B, the semiconductor memory device includes the gate array GAR, the bit line array BAR, a plurality of cell pillar structures CPI, a doped semiconductor structure DPS, and a peripheral circuit structure PCS. The gate array GAR, the bit line array BAR, and the doped semiconductor structure DPS are disposed over the peripheral circuit structures PCS. The gate array GAR is disposed between the bit line array BAR and the doped semiconductor structure DPS. The plurality of cell pillar structures CPI penetrate the gate array GAR.

The gate array GAR includes a plurality of conductive layers CL1, CL2, and CL3. Each of the plurality of conductive layers CL1, CL2, and CL3 may extend in parallel to a first plane. In an embodiment, the first plane may be an XY plane. The plurality of conductive layers CL1, CL2, and CL3 may be arranged to be spaced apart from each other in a stacking direction crossing the first plane. In an embodiment, the stacking direction a Z-axis direction crossing the XY plane. Each of the plurality of conductive layers CL1, CL2, and CL3 may include various conductive materials such as a doped semiconductor layer and a metal layer. The doped semiconductor layer may include a doped silicon layer. The metal layer may include tungsten, copper, molybdenum, or the like. Each of the plurality of conductive layers CL1, CL2, and CL3 may further include a metal nitride layer. The metal nitride layer may include titanium nitride, tantalum nitride, or the like.

The plurality of conductive layers CL1, CL2, and CL3 may include at least one first conductive layer CL1, a plurality of second conductive layers CL2, and at least one third conductive layer CL3. The plurality of second conductive layers CL2 are arranged to be spaced apart from each other in the stacking direction between the first conductive layer CL1 and the third conductive layer CL3. The first conductive layer CL1 is disposed closer to the doped semiconductor structure DPS than the plurality of second conductive layers CL2, and the third conductive layer CL3 is disposed closer to the bit line array BAR than the plurality of the second conductive layers CL2. The first conductive layer CL1 may serve as the source select line SSL as shown in FIG. 1, a plurality of second conductive layers CL2 may serve as the plurality of word lines WL as shown in FIG. 1 and the third conductive layer CL3 may serve as the drain select line DSL as shown in FIG. 1.

The plurality of conductive layers CL1, CL2, and CL3 may be alternately arranged with the plurality of insulating layers IL1, IL2, and IL3 in the stacking direction. Each of the plurality of insulating layers IL1, IL2, and IL3 may include an insulating material such as a silicon oxide layer or a silicon oxynitride layer. The plurality of insulating layers IL1, IL2, and IL3 include a first insulating layer IL1, a plurality of second insulating layers IL2, and a third insulating layer IL3. The first insulating layer IL1 is disposed between the doped semiconductor structure DPS and the first conductive layer CL1, the third insulating layer IL3 is disposed between the bit line array BAR and the third conductive layer CL3, and the plurality of second insulating layers IL2 are arranged to be spaced apart from each other in the stacking direction between the first insulating layer IL1 and the second insulating layer IL2. The plurality of conductive layers CL1, CL2, and CL3 and the plurality of insulating layers IL1, IL2, and IL3 may form a gate stack GST.

The plurality of cell pillar structures CPI extend in the stacking direction to penetrate the gate stack GST. Each of the plurality of conductive layers CL1, CL2, and CL3 may surround a sidewall of each of the cell pillar structures CPI. The cell pillar structure CPI includes a plurality of memory cell string areas. The plurality of memory cell string areas respectively correspond to a plurality of bit lines of the bit line array BAR, and each memory cell string area is controlled by a bit line corresponding thereto. In an embodiment, the cell pillar structure CPI may include a first memory cell string area AR1 and a second memory cell string area AR2, and the bit line array BAR may include a first bit line BL1 corresponding to the first memory cell string area AR1 and a second bit line BL2 corresponding to the second memory cell string area AR2. Each of the plurality of conductive layers CL1, CL2, and CL3 may control all of the plurality of memory cell string areas of the cell pillar structure CPI. As an embodiment, each of the first conductive layer CL1, the second conductive layer CL2, and the third conductive layer CL3 may have an all-around structure surrounding a sidewall of the cell pillar structure CPI to control both the first memory cell string area AR1 and the second memory cell string area AR2.

Though not shown in FIGS. 2A and 2B, a plurality of conductive bit line connection structures may be disposed between the bit line array BAR and the plurality of cell pillar structures CPI. Each conductive bit line connection structure may couple a corresponding bit line (e.g., BL1) to a corresponding conductive capping pattern (e.g., CAP1 as shown in FIG. 3), and may be designed with various structures accordingly. The conductive capping pattern may be disposed in a memory cell string area of the cell pillar structure CPI, which will be described below with reference to FIG. 3.

The plurality of bit lines (e.g., BL1, BL2) of the bit line array BAR may extend in the X-axis direction and may be spaced apart in the Y-axis direction. The doped semiconductor structure DPS may be spaced apart from the bit line array BAR in the Z-axis direction. One of the doped semiconductor structure DPS and the bit line array BAR may be disposed closer to the peripheral circuit structure PCS than the other. In an embodiment, as shown in FIG. 2A, the doped semiconductor structure DPS may be disposed closer to the peripheral circuit structure PCS than the bit line array BAR. In an embodiment, as shown in FIG. 2B, the bit line array BAR may be disposed closer to the peripheral circuit structure PCS than the doped semiconductor structure DPS.

Referring to FIGS. 2A and 2B, the doped semiconductor structure DPS includes at least one doped semiconductor layer extending on the XY plane. The doped semiconductor layer of the doped semiconductor structure DPS may include n-type impurities or p-type impurities. In an embodiment, the doped semiconductor structure DPS may include one or both of a first conductivity type doped semiconductor layer including n-type impurities as majority carriers and a second conductivity type doped semiconductor layer including p-type impurities as majority carriers. The first conductivity type doped semiconductor layer may serve as the common source layer CSR as described with reference to FIG. 1, and the second conductivity type doped semiconductor layer may serve as a well region.

The cell pillar structure CPI includes a contact surface which is in contact with the doped semiconductor structure DPS. The contact surface may be formed on a part of a sidewall of the cell pillar structure CPI, an end of the cell pillar structures CPI, and the like.

The peripheral circuit structure PCS may include an input/output circuit, a control circuit, a voltage generation circuit, a row decoder, a column decoder, a page buffer, and the like, and may include a plurality of transistors PTR constituting at least a part thereof and a plurality of interconnections IC coupled to the plurality of transistors PTR.

Each transistor PTR is disposed in an active region of the semiconductor substrate SUB partitioned by an isolation layer ISO. The semiconductor substrate SUB includes a semiconductor material. In an embodiment, the semiconductor material may include one or more of a group IV semiconductor, a group III-V compound semiconductor, and a group II-VI compound semiconductor. Group IV semiconductors may include single crystal silicon (Si), polycrystalline silicon, germanium (Ge), and silicon germanium (SiGe). Group III-V compound semiconductors may include GaAs, GaN, GaP, GaAsP, GaInASP, AlAs, AlGa, InP, InSb, and InGaAs. Group II-VI compound semiconductors may include ZnS, ZnO, and CdS.

The semiconductor substrate SUB may further include a dielectric layer. In an embodiment, the semiconductor substrate SUB may be a silicon-on-insulating material (SOI) substrate or a germanium-on-insulating material (GeOI) substrate. The semiconductor substrate SUB may further include an organic material. In an embodiment, the semiconductor substrate SUB may include graphene.

The semiconductor substrate SUB may be a bulk wafer or an epitaxial layer grown by selective epitaxial growth (SEG). Alternatively, the semiconductor substrate SUB may be a layer formed by a Metal Induced Lateral Crystallization (MILC) method, and may partially include metal.

The semiconductor substrate SUB may have a single crystalline, polycrystalline, or amorphous state. The semiconductor substrate SUB may include Group II, III, IV, V, or VI impurities. In an embodiment, the semiconductor substrate SUB may include an n-well region doped with n-type impurities, a p-well region doped with p-type impurities, or an n-well region and a p-well region.

The transistor PTR is covered by a peripheral insulation structure PIS. The peripheral insulation structure PIS is disposed over the semiconductor substrate SUB. The plurality of interconnections IC may be formed in the peripheral insulation structure PIS and include a plurality of conductive lines and a plurality of conductive contacts for electrical connection.

Referring to FIG. 2A, the doped semiconductor structure DPS may be disposed on the peripheral insulation structure PIS.

Referring to FIG. 2B, the semiconductor memory device may further include a bonding structure BS. The bonding structure BS may be disposed between the bit line array BAR and the peripheral circuit structure PCS. The bonding structure BS includes a first intervening insulation structure IS1, a second intervening insulation structure IS2, a first conductive bonding pattern BDP1, and a second conductive bonding pattern BDP2. The first intervening insulation structure IS1 is disposed between the bit line array BAR and the peripheral insulation structure PIS, and the second intervening insulation structure IS2 are disposed between the first intervening insulation structure IS1 and the peripheral insulation structures PIS. The first intervening insulation structure IS1 is bonded to the second intervening insulation structure IS2. The first conductive bonding pattern BDP1 is disposed in the first intervening insulation structure IS1, and the second conductive bonding pattern BPD2 is disposed in the second intervening insulation structure IS2. The first conductive bonding pattern BDP1 is bonded to the second conductive bonding pattern BPD2 and is electrically coupled to the second conductive bonding pattern BDP2.

The cell pillar structure CPI shown in FIG. 2A or 2B may be configured to realize two or more strings of memory cells. Hereinafter, a cell pillar structure according to an embodiment of the present disclosure will be described with reference to FIG. 3.

FIG. 3 is a diagram illustrating the gate stack GST and the cell pillar structure CPI according to an embodiment of the present disclosure.

FIG. 3 illustrates a part of the gate stack GST as shown in FIG. 2A or 2B, and the first conductive layer CL1 and the first insulating layer IL1 among the first conductive layer CL1, the plurality of second conductive layers CL2, the third conductive layer CL3, the first insulating layer IL1, the plurality of second insulating layers IL2, and the third insulating layer IL3 as shown in FIG. 2A or 2B are not shown.

Referring to FIG. 3, the cell pillar structure CPI extends in the stacking direction (e.g., in the Z-axis direction) which crosses the XY plane. The cell pillar structure CPI includes the isolation structure SS, a capping layer isolation structure CSS, the channel layer CHL partitioned by two or more channel portions (e.g., CH1 and CH2), two or more memory portions (e.g., ML1 and ML2) corresponding to the two or more channel portions, and two or more conductive capping patterns (e.g., CAP1 and CAP2) corresponding to the two or more channel portions.

The channel layer CHL includes semiconductor materials such as silicon (Si), germanium (Ge), or mixtures thereof. The channel layer CHL is divided into two or more channel portions by the isolation structure SS. In an embodiment, the channel layer CHL may be divided into the first channel portion CH1 and the second channel portion CH2 by the isolation structure SS. Each channel portion serves as a channel region of a corresponding memory cell string. In an embodiment, the first channel portion CH1 may serve as a channel region of the first memory cell string, and the second channel portion CH2 may serve as the channel region of the second memory cell string. The channel layer CHL may extend by a height at which the third insulating layer IL3 of the gate stack GST is disposed.

The isolation structure SS includes an insulating material. The isolation structure SS might not reach the height at which the third insulating layer IL3 is disposed, and may have a smaller length than the channel layer CHL in the stacking direction. As a result, an upper end of each of the two or more channel portions may protrude in the stacking direction more than the isolation structure SS.

A buffer pattern (e.g., BU1 or BU2) may be disposed between the isolation structure SS and each channel portion. In an embodiment, a first buffer pattern BU1 may be disposed between the isolation structure SS and the first channel portion CH1, and the second buffer pattern BU2 may be disposed between the isolation structure SS and the second channel portion CH2. Each buffer pattern may include an insulating material.

Two or more conductive capping patterns (e.g., CAP1 and CAP2) include a doped semiconductor layer. The doped semiconductor layer may include n-type impurities, or both n-type and p-type impurities. In one embodiment, two or more conductive capping patterns may include n-type impurities as majority carriers and may be provided as drain regions. The top of the protruding channel portion may be doped with the same impurities as the corresponding conductive capping pattern.

Two or more conductive capping patterns (e.g., CAP1 and CAP2) and the capping layer isolation structure CSS may overlap the isolation structure SS in the stacking direction. The capping layer isolation structure CSS includes an insulating material. Two or more conductive capping patterns are spaced apart from each other by the capping layer isolation structure CSS. In an embodiment, the doped semiconductor layer may be separated into a first conductive capping pattern CAP1 and a second conductive capping pattern CAP2 by the capping layer isolation structure CSS. Each conductive capping pattern may be coupled to a corresponding channel portion, and may be integrated with the corresponding channel portion by heat treatment such as laser annealing. In an embodiment, the first conductive capping pattern CAP1 may be coupled to the first channel CH1 and may be integrated with the first channel CH1, and the second conductive capping pattern CAP2 may be coupled to and integrated with the second channel CH2. Each conductive capping pattern is coupled to a corresponding bit line via a conductive bit line connection structure. In an embodiment, the first conductive capping pattern CAP1 may be coupled to the first bit line BL1 of the bit line array BAR as shown in FIG. 2A or 2B, and the second conductive capping pattern CAP2 may be coupled to a second bit line BL2 of the bit line array BAR as shown in FIG. 2A or 2B.

Each of the two or more memory portions (e.g., ML1 and ML2) is disposed between a corresponding channel portion and the gate stack GST. In an embodiment, the first memory portion ML1 may be disposed between the first channel portion CH1 and the gate stack GST, and the second memory portion ML2 may be disposed between the second channel portion CH2 and the gate stack GST.

The channel layer CHL may include a contact surface in contact with the doped semiconductor structure DPS as shown in FIG. 2A or 2B. The contact surface may be designed in a variety of ways. Hereinafter, the contact surface according to embodiments of the present disclosure will be described with reference to FIGS. 4A, 4B, and 4C.

FIGS. 4A to 4C are cross-sectional views illustrating the doped semiconductor structure DPS and the cell pillar structure CPI according to embodiments of the present disclosure.

Parts of the gate stack GST are as shown in FIGS. 4A to 4C, and the third conductive layer CL3 and the third insulating layer IL3 among the first conductive layer CL1, the plurality of second conductive layers CL2, the third conductive layer CL3, the first insulating layer IL1, the plurality of the second insulating layers IL2, and the third insulating layer IL3 as shown in FIG. 2A or 2B are not shown in FIGS. 4A to 4C. Part of the cell pillar structure CPI is shown in FIGS. 4A to 4C.

Referring to FIGS. 4A to 4C, the cell pillar structure CPI may penetrate the gate stack GST to be in contact with the doped semiconductor structure DPS. The channel layer CHL of the cell pillar structure CPI includes a contact surface CTS in contact with the doped semiconductor structure DPS.

The channel layer CHL may include two or more channel portions (e.g., CH1 and CH2) and a channel connecting portion CHC connecting the channel portions. The channel connecting portion CHC may constitute a closed end of the channel layer CHL. The channel connecting portion CHC may extend to connect two or more channel portions (e.g., CH1 and CH2) to each other. In an embodiment, the first channel portion CH1 and the second channel portion CH2 may be spaced apart from each other by the isolation structure SS in the XY plane, and the channel connecting portion CHC may extend from the first channel portion CH1 toward the second channel portion CH2.

A buffer layer BUL may be disposed between the channel layer CHL and the isolation structure SS. The buffer layer BUL may include an insulating material. The buffer patterns (e.g., BU1 and BU2) are portions of the buffer layer BUL and extend on the inner walls the two or more channel portions (e.g., CH1 and CH2) respectively. The buffer patterns may be coupled by a buffer connecting pattern BUC. The buffer connecting pattern BUC is another part of the buffer layer BUL and extends in parallel to the channel connecting portion CHC of the channel layer CHL.

The doped semiconductor structure DPS includes at least one doped semiconductor layer. The contact surface CTS of the channel layer CHL in contact with the doped semiconductor structure DPS may be formed on the sidewall of each channel portion or the channel connecting portion CHC.

Referring to FIG. 4A, according to an embodiment, the doped semiconductor structure DPS may include a first doped semiconductor layer L1, a second doped semiconductor layer L2, and a third doped semiconductor layer L3 which are stacked in the Z-axis direction. The cell pillar structure CPI may penetrate the third doped semiconductor layer L3 of the doped semiconductor structure DPS and extend into the first doped semiconductor layer L1. The contact surface CTS of the channel layer CHL may be formed between the second doped semiconductor layer L2 of the doped semiconductor structure DPS and the channel layer CHL.

Each of the first doped semiconductor layer L1, the second doped semiconductor layer L2, and the third doped semiconductor layer L3 may include n-type impurities, p-type impurities, or a mixture thereof. In an embodiment, each of the first doped semiconductor layer L1, the second doped semiconductor layer L2, and the third doped semiconductor layer L3 may include n-type impurities as majority carriers. However, embodiments of the present disclosure are not limited thereto. In an embodiment, the doped semiconductor structure DPS may include an n-type impurity region including n-type impurities as majority carriers and a p-type impurity region including p-type impurities as the plurality of carriers. For example, the second doped semiconductor layer L2 may constitute an n-type impurity region, and either or both of the first doped semiconductor layer L1 and the third doped semiconductor layer L3 may constitute a p-type impurity region.

Each of the two or more memory portions (e.g., ML1 and ML2) is disposed between the gate stack GST and the channel layer CHL, and may extend between the third doped semiconductor layer L3 and the channel layer. A dummy memory portion DML may be disposed between the first doped semiconductor layer L1 and the channel layer CHL. The second doped semiconductor layer L2 extends between each of the two or more memory portions and the dummy memory portion DML. In an embodiment, the second doped semiconductor layer L2 extends between each of the first memory portion ML1 and the second memory portion ML2 and the dummy memory portion DML.

The second doped semiconductor layer L2 may surround the sidewall of the channel layer CHL between the first doped semiconductor layer L1 and the third doped semiconductor layer L3. The contact surface CTS may be formed on the sidewall of the channel layer CHL. The sidewall of the channel layer CHL may be formed of a part of each channel portion (e.g., CH1 or CH2).

Referring to FIGS. 4B and. 4C, in an embodiment, the doped semiconductor structure DPS may include an n-type impurity region, or may include both an n-type impurity region and a p-type impurity region. The contact surface CTS of the channel layer CHL may be formed between the n-type impurity region of the doped semiconductor structure DPS and the channel layer CHL.

Referring to FIG. 4B, in an embodiment, the contact surface CTS of the channel layer CHL may be formed on the channel connecting portion CHC of the channel layer CHL. Each of the two or more memory portions (e.g., ML1 and ML2) is disposed between the gate stack GST and the channel layer CHL, and may be spaced apart from each other with the channel connecting portion CHC disposed between the two or more memory portions.

Referring to FIG. 4C, in an embodiment, the contact surface CTS of the channel layer CHL may be formed on a groove of the doped semiconductor structure DPS. Each of the channel layer CHL, the buffer layer BUL, and the isolation structure SS may extend into the groove of the doped semiconductor structure DPS. A portion of each of the two or more channel portions (e.g., CH1 and CH2) of the channel layer CHL and the channel connecting portion CHC are disposed in the groove of the doped semiconductor structure DPS. A portion of each of the two or more channel portions (e.g., CH1 and CH2) disposed in the groove of the doped semiconductor structure DPS and the channel connecting portion CHC may form the contact surface CTS of the channel layer CHL. Each of the two or more memory portions (e.g., ML1 and ML2) is disposed between the gate stack GST and the channel layer CHL and does not extend into the groove of the doped semiconductor structure DPS.

Referring to FIGS. 4A to 4C, each of the two or more memory portions (e.g., ML1 and ML2) and the dummy memory portion DML includes a tunnel insulating layer TI, a data storage layer DS, and a blocking insulating layer BI. The tunnel insulating layer TI extends on the outer wall of the channel layer CHL and may include an oxide such as silicon dioxide (SiO₂). The blocking insulating layer BI extends on the outer wall of the tunnel insulating layer TI, and may include an oxide such as silicon dioxide (SiO₂), a high-k dielectric insulating material including a higher dielectric constant than the silicon dioxide, and the like. The high-k dielectric insulating material may include an aluminum oxide layer, a hafnium oxide layer, or the like. The data storage layer DS is disposed between the tunnel insulating layer TI and the blocking insulating layer BI.

The data storage layer DS of each of the two or more memory portions (e.g., ML1 and ML2) extends continuously in the stacking direction or is separated into data storage patterns spaced apart from each other in the stacking direction. In an embodiment, as shown in FIGS. 4A to 4C, the data storage layer DS may continuously extend in the stacking direction on sidewalls of the plurality of insulating layers IL1 and IL2 and the plurality of conductive layers CL1 and CL2. Though not shown, in an embodiment, the data storage layer DS may be cut at levels at which the plurality of insulating layers IL1 and IL2 are disposed to be separated into a plurality of data storage patterns. The plurality of data storage patterns may be respectively disposed at levels at which the plurality of conductive layers CL1 and CL2 are disposed. In other words, each data storage pattern may be a data storage layer DS disposed between a corresponding conductive layer and the tunnel insulating layer TI. The data storage layer DS may include a material layer of storing data which is changed by using Fowler-Nordheim tunneling. In an embodiment, the data storage layer DS may include a charge trap insulating layer, a floating gate layer, or an insulating layer including conductive nanodots. The charge trap insulating layer may include a silicon nitride layer. The data storage layer which is formed of a floating gate layer is separated into a plurality of data storage patterns as described above. The data storage layer which is formed of a charge trap insulating layer or an insulating layer including conductive nanodots is separated into a plurality of data storage patterns or continuously extends in the stacking direction as in the data storage layer DS as shown in FIGS. 4A to 4C.

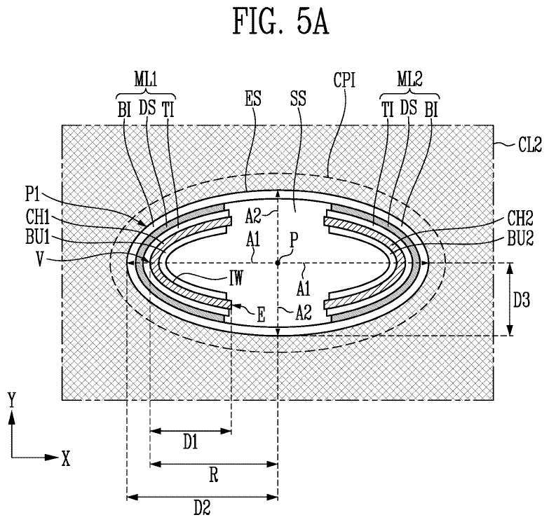

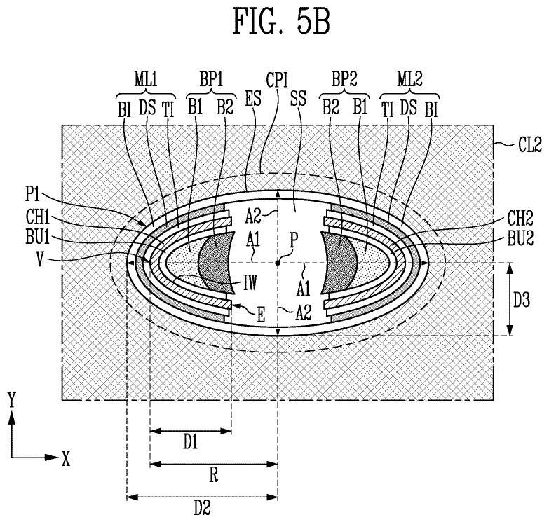

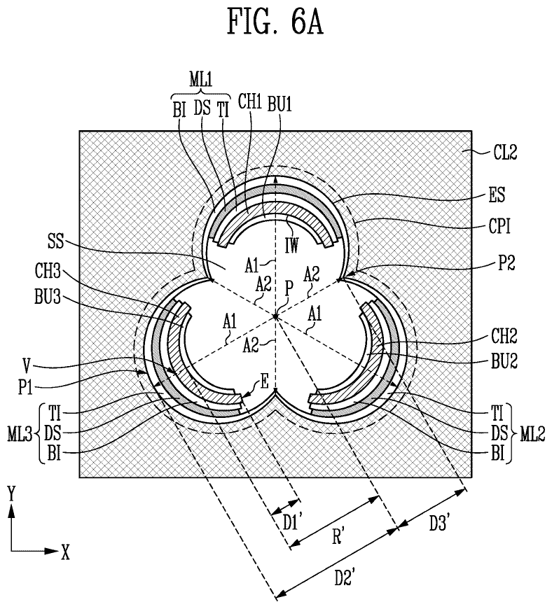

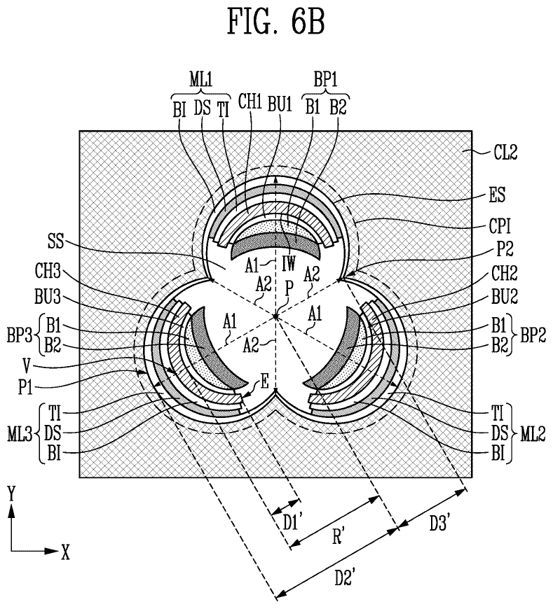

The cross section of the cell pillar structure CPI which is taken in a direction parallel to the XY plane may be designed in various ways, taking into account the processes of separating the channel layer CHL into two or more channel portions. Hereinafter, the cross section of the cell pillar structure CPI will be described with reference to FIGS. 5A, 5B, 6A, and 6B.

FIGS. 5A, 5B, 6A and 6B are plan views showing a cross-section of a cell pillar structure according to embodiments of the present disclosure.

FIGS. 5A, 5B, 6A, and 6B show the cross section of the cell pillar structure CPI at the level where the second conductive layer CL2 served as a word line is disposed. Hereinafter, the cross section of the cell pillar structure CPI will be described with reference to a plurality of first axes A1 and a plurality of second axes A2. The plurality of first axes A1 and the plurality of second axes A2 extend radially from a center point P of the cell pillar structure CPI in the XY plane.

Referring to FIGS. 5A, 5B, 6A and 6B, an external surface ES of the cell pillar structure CPI is spaced apart from the center point P. The plurality of first axes A1 and the plurality of second axes A2 face the external surface ES of the cell pillar structure CPI from the center point P. The plurality of first axes A1 and the plurality of second axes A2 are alternately arranged clockwise. Each of the plurality of conductive layers CL1, CL2, and CL3 as shown in FIG. 2A or 2B extends to surround the external surface of the cell pillar structure CPI in the XY plane.

The external surface ES of the cell pillar structure CPI may include a plurality of convex portions P1. The plurality of convex portions P1 intersect the plurality of first axes A1, respectively.

The cell pillar structure CPI includes a plurality of channel portions (e.g., CH1, CH2, and CH3) corresponding to the plurality of convex portions P1. The plurality of channel portions intersect the plurality of first axes A1, respectively. Each of the channel portions CH1, CH2, and CH3 extends clockwise and counterclockwise from a vertex V which crosses the corresponding first axis A1. In an embodiment, each channel portion CH1, CH2 or CH3 has a radius of curvature R or R′ formed between the vertex V and the center point P, and may be bent.

In the XY plane, an end E of each channel portion CH1, CH2 or CH3 is disposed at a first distance D1 or D1′ in the extending direction of the first axis A1 from the vertex V. In an embodiment, the first distance D1 or D1′ may be controlled within a range of 30% or more of the radius of curvature R or R′ so that a channel current formed in the channel portion CH1, CH2, or CH3 may be secured during operations of the semiconductor memory device. In an embodiment, the first distance D1 or D1′ may be controlled within a range of 80% or less of the radius of curvature R or R′ to suppress interference failures between the plurality of channel portions (e.g., CH1, CH2, and CH3).

The isolation structure SS is disposed between the plurality of channel portions CH1, CH2, or CH3 and extends toward the center point P.

The cell pillar structure CPI includes a plurality of memory portions (e.g., ML1, ML2, and ML3) corresponding to the plurality of convex portions P1. Each memory portion ML1, ML2, or ML3 is disposed between a corresponding channel portion and a conductive layer (e.g., CL2) of the gate array. The tunnel insulating layer TI, the data storage layer DS, and the blocking insulating layer BI of each of the memory portions ML1, ML2, and ML3 may extend on the external surface ES of the cell pillar structure CPI. Some of the tunnel insulating layer TI, the data storage layer DS, and the blocking insulating layer BI may be penetrated by the isolation structure SS. In an embodiment, the isolation structure SS may extend on the plurality of second axes A2 from the center point P to penetrate the tunnel insulating layer TI and the data storage layer DS, and the blocking insulating layer BI may be continuous in the XY plane on the external surface ES of the cell pillar structure CPI without being penetrated by the isolation structure SS to be of a hollow type. However, embodiments of the present disclosure are not limited thereto. Though not shown, in an embodiment, the isolation structure SS may penetrate the blocking insulating layer BI, and the blocking insulating layer BI may be divided into a plurality of portions in the XY plane. The blocking insulating layer BI is disposed between the conductive layer (e.g., CL2) of the gate array and each of the channel portions CH1, CH2, and CH3. The data storage layer DS is disposed between the blocking insulating layer BI and each of the channels portions CH1, CH2 or CH3. The tunnel insulating layer TI is disposed between the data storage layers DS and each of the channels portions CH1, CH2, and CH3.

The cell pillar structure CPI includes a plurality of buffer patterns (e.g., BU1, BU2, and BU3) corresponding to the plurality of convex portions P1. Each of the buffer patterns BU1, BU2 and BU3 is disposed between an inner wall IW of the corresponding channel portion and the isolation structure SS. The inner wall IW faces the center point P.

The plurality of convex portions P1 of the cell pillar structure CPI may vary depending on the cross-sectional shape of the cell pillar structure CPI.

Referring to FIGS. 5A and 5B, in an embodiment, the cell pillar structure CPI may have a substantially elliptical shape in the XY plane. Two of the first axes A1 facing in opposite directions are aligned on a major axis of the ellipse defined by the cell pillar structure CPI, and two of the second axes A2 facing in opposite directions on a minor axis of the ellipse are aligned. The external surface ES of the cell pillar structure CPI is disposed at a second distance D2 in the extending direction of the first axis A1 from the center point P, and is disposed at a third distance D3 smaller than the second distance D2 in the extending direction of the second axis A2 from the center point P.

Referring to FIGS. 6A and 6B, in an embodiment, the external surface ES of the cell pillar structure CPI may include a plurality of concave portions P2. The plurality of concave portions P2 intersect the plurality of second axes A2, respectively. The external surface ES of the cell pillar structure CPI is disposed at a second distance D2′ in the extending direction of the first axis A1 from the center point P, and is disposed at a third distance D3′ smaller than the second distance D2′ in the extending direction the second axis A2 from the center point P.

The plurality of convex portions P1 may be three or more convex portions, and the plurality of concave portions P2 may also be three or more concave portions. In an embodiment, the external surface ES of the cell pillar structure CPI may include three convex portions P1 and three concave portions P2 so that the external surface ES may have a clover shape.

Referring to FIGS. 5B and 6B, the cell pillar structure CPI may further include a plurality of barrier patterns (e.g., BP1, BP2, and BP3) corresponding to the plurality of convex portions P1. Each of the barrier patterns BP1, BP2 and BP3 is disposed between the corresponding buffer pattern BU1, BU2 or BU3 and the isolation structure SS.

Each of the barrier patterns BP1, BP2, and BP3 may include a seed barrier pattern B1 and a growth barrier pattern B2. The seed barrier pattern B1 is disposed between the corresponding buffer pattern BU1, BU2 or BU3 and the isolation structure SS, and the growth barrier pattern B2 is disposed between seed barrier pattern B1 and the isolation structure SS.

The thickness of each of the seed barrier pattern B1 and the growth barrier pattern B2 is a dimension in the extending direction of the corresponding first axis A1. The thickness of the seed barrier pattern B1 may decrease as the seed barrier pattern B1 approaches the end E of the corresponding channel portion. The growth barrier pattern B2 has a greater thickness uniformity than the seed barrier pattern B1. The thickness uniformity increases as the difference between the thicknesses of a layer to be measured in the direction of the first axis A1 at different positions in the direction of the second axis A2 decreases.

To increase the thickness uniformity, the growth barrier pattern B2 may be formed by area selective atomic layer deposition (AS-ALD), selective epitaxial growth (SEG), or selective poly growth (SPG).

Various manufacturing methods of a semiconductor memory device according to embodiments of the present disclosure are described below.

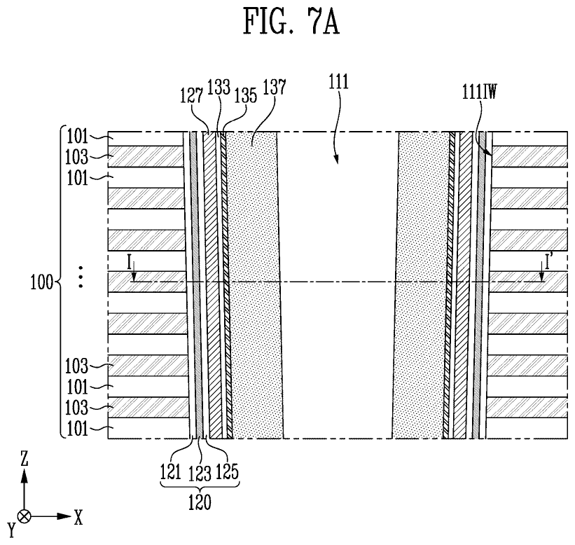

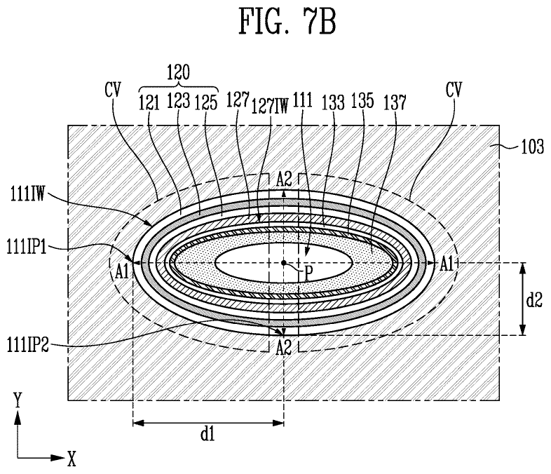

FIGS. 7A and 7B are a cross-sectional view and a plan view showing a stack, a hole, and layers disposed in the hole according to an embodiment of the present disclosure. FIG. 7B is a plan view of a stack 100 shown in FIG. 7A taken along line I-I′.

Referring to FIGS. 7A and 7B, the stack 100 is formed on a lower structure (not shown). The stack 100 includes a plurality of first material layers 101 and a plurality of second material layers 103.

Though not shown, in an embodiment, the lower structure may include the semiconductor substrate SUB as shown in FIG. 2A, the peripheral circuit structure PCS as shown in FIG. 2A, and the doped semiconductor structure DPS as shown in FIG. 2A. In an embodiment, the lower structure may include the semiconductor substrate SUB as shown in FIG. 2A, the peripheral circuit structure PCS as shown in FIG. 2A, and the preliminary semiconductor structure. The preliminary semiconductor structure may include the first doped semiconductor layer L1 as shown in FIG. 4A, the third doped semiconductor layer L3 as shown in FIG. 4A, and a sacrificial structure disposed between the first doped semiconductor layer L1 and the third doped semiconductor layer L3. The sacrificial structure may be replaced with the second doped semiconductor layer L2 as shown in FIG. 4A in subsequent processes. In an embodiment, the lower structure may be a sacrificial substrate including a silicon wafer or the like.

Each of the plurality of first material layers 101 and the plurality of second material layers 103 extends in the XY plane. The plurality of first material layers 101 and the plurality of second material layers 103 are alternately arranged in a stacking direction (e.g., a Z-axis direction) crossing the XY plane. The plurality of first material layers 101 may include an insulating material such as a silicon oxide layer and a silicon oxynitride layer. The plurality of second material layers 103 may include a conductive material, or may include a sacrificial insulating material including an etching selectivity with respect to the plurality of first material layers 101. In an embodiment, the sacrificial insulating material may include a silicon nitride layer. Hereinafter, a method of manufacturing a semiconductor memory device will be described based on an embodiment in which the plurality of first material layers 101 include an insulating material and the plurality of second material layers 103 include a sacrificial insulating material, but an embodiment of the present disclosure is not limited thereto.

Subsequently, a hole 111 extending in the stacking direction is formed to penetrate the plurality of first material layers 101 and the plurality of second material layers 103. The process of forming the hole 111 includes a process of forming a mask pattern (not shown) using a photolithography process and a process of etching the stack 110 using the mask pattern as an etching barrier.

The hole 111 has a first inner wall 111IW. The shape of the cross section of the hole 111 is defined by the first inner wall 111IW in the XY plane. In the XY plane, the first inner wall 111IW is spaced apart from the center point P of the hole 111 and crosses the plurality of first axes A1 and the plurality of second axes A2. The plurality of first axes A1 and the plurality of second axes A2 extend radially from the center point P and are alternately arranged clockwise. In the XY plane, the first inner wall 111IW includes a plurality of convex portions CV which intersect the plurality of first axes A1, respectively.

In an embodiment, a sidewall of the stack 100 adjacent to the hole 111 in the XY plane may form a substantially elliptical shape. Two first axes A1 facing opposite directions are aligned on the major axis of the ellipse by the hole 111, and two second axes A2 facing opposite directions are arranged on the minor axis of the above ellipse. Accordingly, a distance d1 between the center point P and an intersection point 111IP1 between the first inner wall 111IW of the hole 111 and each of the first axes A1 is larger than a distance d2 between the center point P and an intersection point 111IP2 between the first inner wall 111IW of the hole 111 and each of the second axes A2.

Subsequently, a memory layer 120, a channel layer 127, a buffer oxide layer 133, a buffer nitride layer 135, and a seed barrier layer 137 may be sequentially formed in the hole 111. Each of the memory layer 120, the channel layer 127, the buffer oxide layer 133, the buffer nitride layer 135, and the seed barrier layer 137 may extend on the first inner wall 111IW of the hole 111.

The memory layer 120 may include the blocking insulating layer 121, a data storage layer 123, and a tunnel insulating layer 125 extending on the first inner wall 111IW of the hole 111. The blocking insulating layer 121 may include one or both of silicon dioxide and a high-k dielectric insulating material including a higher dielectric constant than silicon dioxide. The data storage layer 123 may include a charge trap insulating layer of a silicon nitride layer or the like. The tunnel insulating layer 125 may include silicon dioxide or the like.

The channel layer 127 is formed on the surface of the tunnel insulating layer 125. The channel layer 127 may include silicon (Si), germanium (Ge), or a mixture thereof. The channel layer 127 has a second inner wall 127IW facing the center point P.

Each of the buffer oxide layer 133, the buffer nitride layer 135, and the seed barrier layer 137 extends on the second inner wall 127IW of the channel layer 127. The buffer oxide layer 133 has an etching selectivity with respect to the data storage layer 123. The buffer nitride layer 135 extends on the surface of the buffer oxide layer 133. The buffer nitride layer 135 has an etching selectivity with respect to the tunnel insulating layer 125.

The seed barrier layer 137 extends on the surface of the buffer nitride layer 135. The seed barrier layer 137 may have an etching selectivity with respect to the buffer nitride layer 135 and the buffer oxide layer 133. In an embodiment, the seed barrier layer 137 may include silicon.

When the seed barrier layer 137 is deposited, the deposition thickness is controlled to be greater in the extending direction of the first axis A1 than in the extending direction of the second axis A2 by using the cross-sectional shape of the first inner wall 111IW of the hole 111. In an embodiment, the center region of the hole 111 opened by the buffer nitride layer 135 may have an elliptical shape on the surface of the buffer nitride layer 135 in the XY plane. The thickness of the seed barrier layer 137 may be formed greater than that of the channel layer 127 in the direction of the first axis A1 so that the difference in deposition thickness is induced on the major axis and the minor axis of the ellipse.

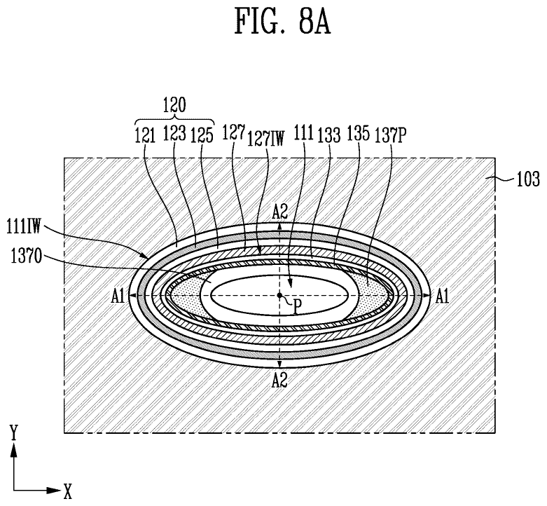

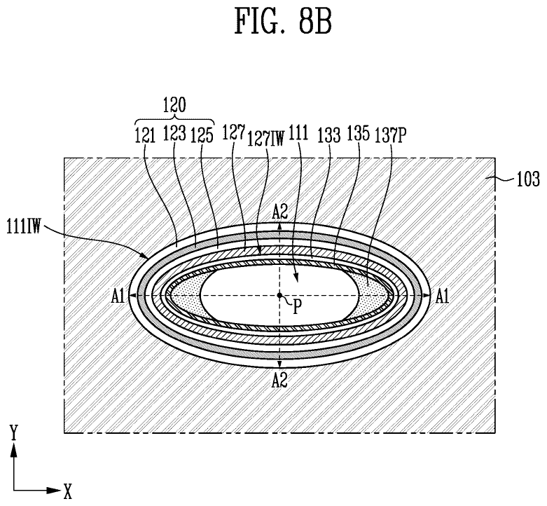

FIGS. 8A and 8B are plan views illustrating seed barrier patterns according to an embodiment of the present disclosure.

Referring to FIG. 8A, a partial region of the seed barrier layer 137 as shown in FIG. 7B is oxidized through the hole 111 to form a seed oxidation region 1370. The oxidation process is controlled such that the seed oxidation region 1370 may be in contact with a partial region of the buffer nitride layer 135 crossing the second axis A2 and is spaced apart from another partial region of the buffer nitride layer 125 crossing the first axis A1. The seed barrier layer 137 as shown in FIG. 7B is partitioned into a plurality of seed barrier patterns 137P by a seed oxidation region 1370 in the hole 111.

Referring to FIG. 8B, the seed oxidation region 1370 as shown in FIG. 8A is selectively removed. The plurality of seed barrier patterns 137P intersect the plurality of first axes A1, respectively, and are alternately arranged clockwise with the plurality of second axes A2.

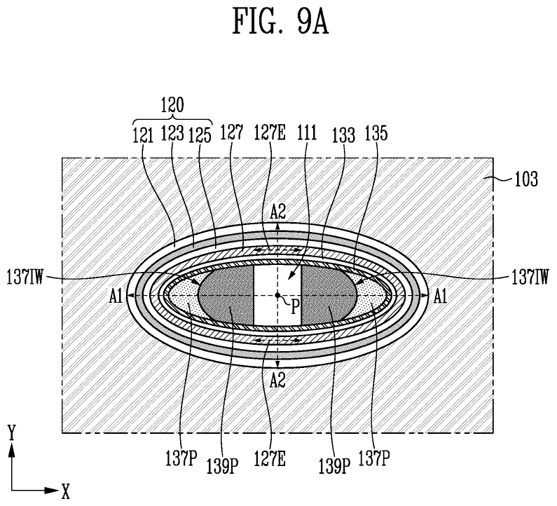

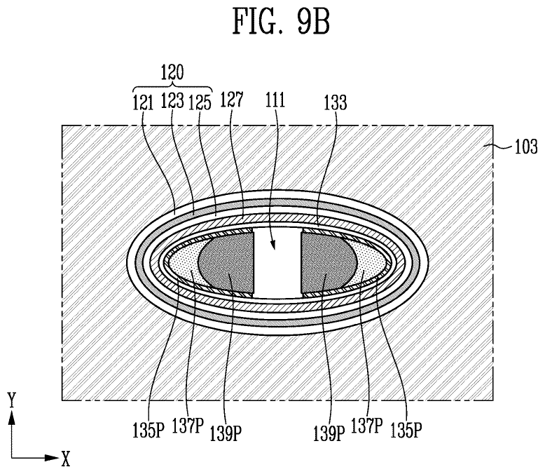

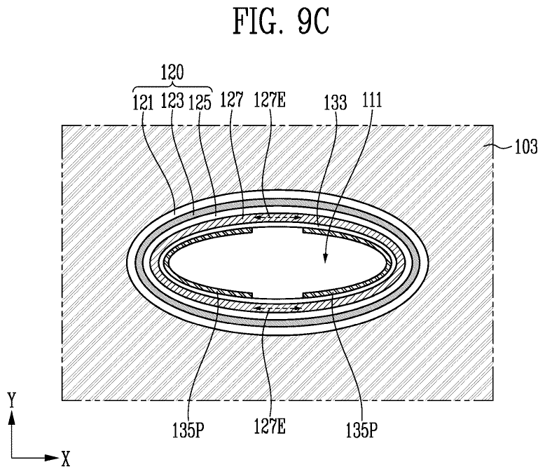

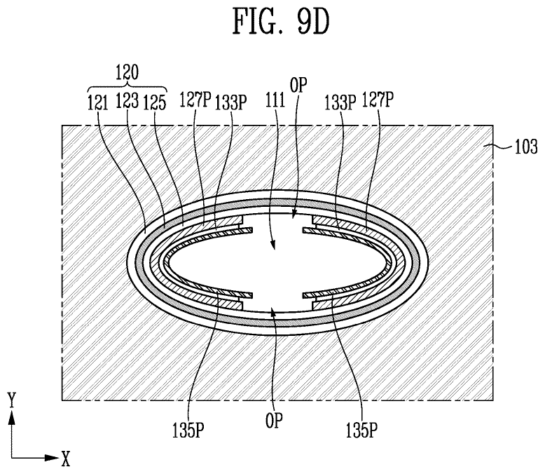

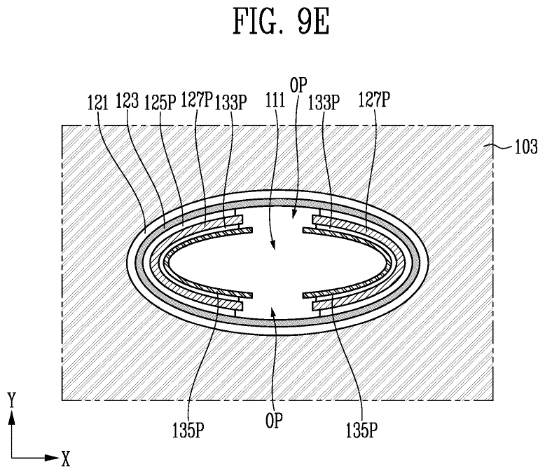

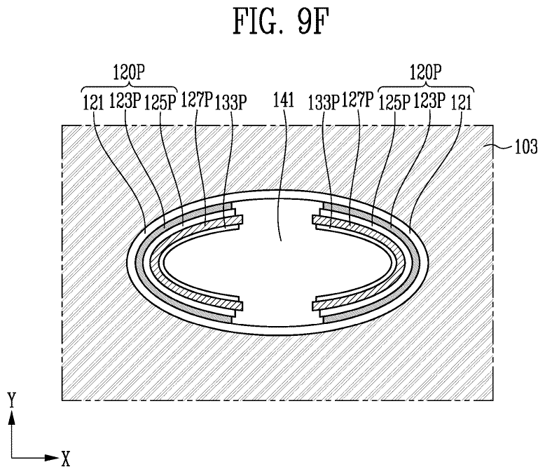

FIGS. 9A to 9F are plan views illustrating growth barrier patterns, buffer patterns, channel portions, and memory portions according to an embodiment of the present disclosure.

Referring to FIG. 9A, a plurality of growth barrier patterns 139P are selectively grown from a plurality of third inner walls 137IW of the plurality of seed barrier patterns 137P toward the center point P. A plurality of etching targets 127E of the channel layer 127 crossing the plurality of second axes A2 are opened between the plurality of growth barrier patterns 139P.

In one embodiment, the growth barrier pattern 139P including silicon may be selectively grown from the seed barrier pattern 137P including silicon by using an SPG method. The seed barrier pattern 137P grown using the SPG method has a greater thickness uniformity than the seed barrier pattern 139P formed by the deposition method. The growth barrier pattern 139P grown using the SPG method may compensate for the thickness of the seed barrier pattern 137P in the direction of the first axis A1, and the growth thickness may be controlled to be spaced apart from the second axis A2. The area of the etching target 127E of the channel layer 127 overlapping the second axis A2 may be controlled according to the growth thickness of the growth barrier pattern 139P.

Referring to FIG. 9B, by removing a plurality of regions of the buffer nitride layer 135 exposed between the plurality of growth barrier patterns 139P shown in FIG. 9A, the buffer nitride layer 135 may be partitioned into a plurality of primary buffer patterns 135P. Each primary buffer pattern 135P is protected by the seed barrier pattern 137P and the growth barrier pattern 139P corresponding thereto.

Referring to FIG. 9C, the plurality of seed barrier patterns 137P and the plurality of growth barrier patterns 139P as shown in FIG. 9B are selectively removed. As a result, the plurality of primary buffer patterns 135P may be exposed.

Referring to FIG. 9D, a plurality of regions of the buffer oxide layer 133 exposed between the plurality of primary buffer patterns 135P shown in FIG. 9C and the plurality of etching targets 127E of the channel layer 127 are sequentially removed. Thus, the buffer oxide layer 133 as shown in FIG. 9C may be divided into a plurality of secondary buffer patterns 133P. In addition, the plurality of openings OP are respectively formed in regions where the plurality of etching targets 127E as shown in FIG. 9C are removed, and the channel layer 127 as shown in FIG. 9C may be partitioned into a plurality of channel portions 127P by the plurality of opening OP penetrating through the channel layer.

Referring to FIG. 9E, by removing a plurality of regions of the tunnel insulating layer 125 as shown in FIG. 9D through the plurality of openings OP, the tunnel insulating layer 123 as shown in FIG. 9D may be partitioned into a plurality of portions 125P. The plurality of secondary buffer patterns 133P are protected by the plurality of primary buffer patterns 135P.

Referring to FIG. 9F, by removing a plurality of regions of the data storage layer 123 as shown in FIG. 9E through a plurality of openings OP, the data storage layer 123 as shown in FIG. 9E may be partitioned into a plurality of portions 123P. The plurality of primary buffer patterns 135P as shown in FIG. 9E together with the plurality of regions of the data storage layer 123 as shown in FIG. 9E may be removed.

Subsequently, an isolation structure 141 may be formed by filling the opening OP and the hole 111 as shown in FIG. 9E with an insulating material. The isolation structure 141 extends spaces between the plurality of portions 125P of the tunnel insulating layer and spaces between the plurality of portions 123P of the data storage layer. A plurality of memory portions 120P corresponding to the plurality of channel portions 127P may be partitioned by the isolation structure 141. Each of the memory portions 120P may include the portion 125P of the tunnel insulating layer, the portion 123P of the data storage layer, and a blocking insulating layer 121.

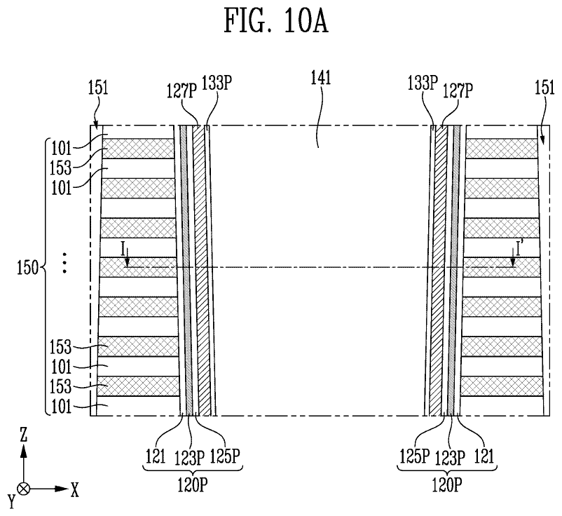

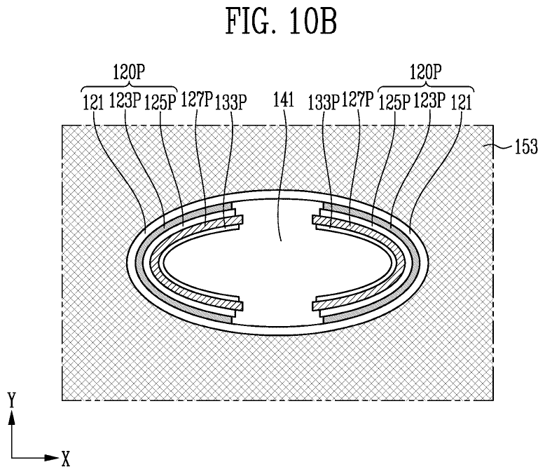

FIGS. 10A and 10B are a cross-sectional view and a plan view showing a gate stack 150 according to an embodiment of the present disclosure. FIG. 10B is a plan view of the gate stack 150 shown in FIG. 10A taken along line I-I′.

Referring to FIGS. 10A and 10B, a slit 151 is formed through the stack including the first material layer 101 and the second material layer 103 shown in FIG. 9B. Subsequently, the second material layer 103 may be replaced with a conductive material through the slit 151. Accordingly, the gate stack 150 including the plurality of first material layers 101 and a plurality of conductive layers 153 alternately arranged in the stacking direction (e.g., the Z-axis direction) may be formed. However, embodiments of the present disclosure are not limited thereto. In an embodiment, when the second material layer 103 shown in FIG. 9B includes a conductive material, the second material layer 103 may constitute the gate stack 150.

In the XY plane, each conductive layer 153 may extend to surround the plurality of memory portions 120P partitioned by the isolation structure 141 and the plurality of channel portions 127P partitioned by the isolation structure 141.

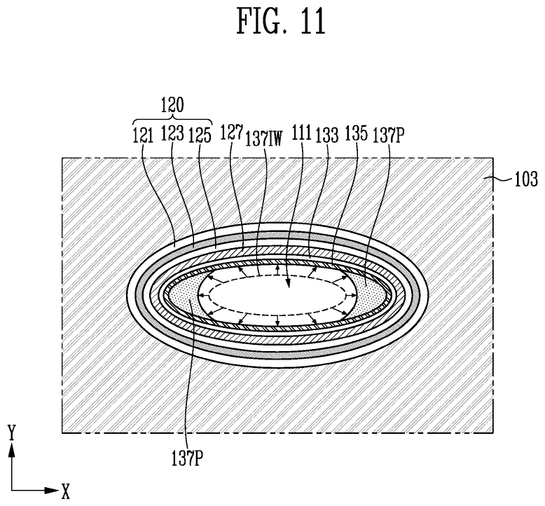

FIG. 11 is a plan view showing seed barrier patterns according to an embodiment of the present disclosure.

Referring to FIG. 11, a plurality of seed barrier patterns 137P are formed in a hole 111 which passes through the plurality of first material layers 101 and the plurality of second material layers 103 shown in FIGS. 7A and 7B. The hole 111 penetrates the plurality of first material layers 101 and the plurality of second material layers 103 of the stack 100 as shown in FIGS. 7A and 7B, and has the same cross-sectional shape as described with reference to FIGS. 7A, 7B in the XY plane. In an embodiment, the hole 111 may have an elliptical cross section.

Before the plurality of seed barrier patterns 137P are formed, as described with reference to FIGS. 7A and 7B, the blocking insulating layer 121, the data storage layer 123, and the tunnel insulating layer 125 of the memory layer 120, the channel layer 127, the buffer oxide layer 133, the buffer nitride layer 135, and the seed barrier layer 137 may be formed in the hole 111. The plurality of seed barrier patterns 137P are some regions of the seed barrier layer 137 as shown in FIGS. 7A and 7B. Reference characters “137IW” in FIG. 11 denote an inner wall of the seed barrier layer 137 as shown in FIGS. 7A and 7B. The seed barrier layer 137 as shown in FIGS. 7A and 7B may be etched from the inner wall 137IW of the seed barrier layer 137 through the hole 111 by a wet etch process or the like. By the etching process, the seed barrier layer 137 as shown in FIGS. 7A and 7B may be partitioned into the plurality of seed barrier patterns 137P.

After the plurality of seed barrier patterns 137P are formed, the processes as described with reference to FIGS. 9A to 9F and FIGS. 10A and 10B may be performed.

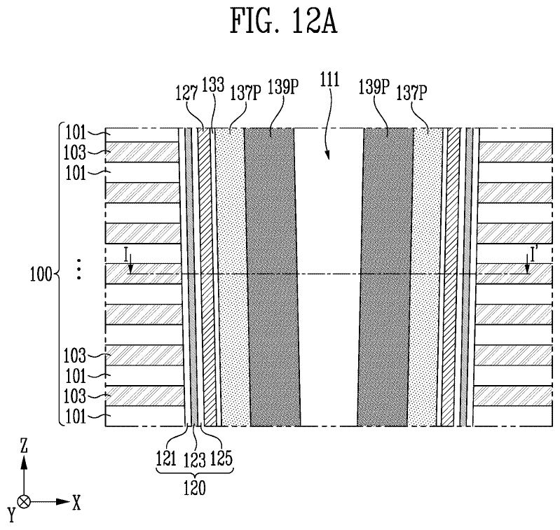

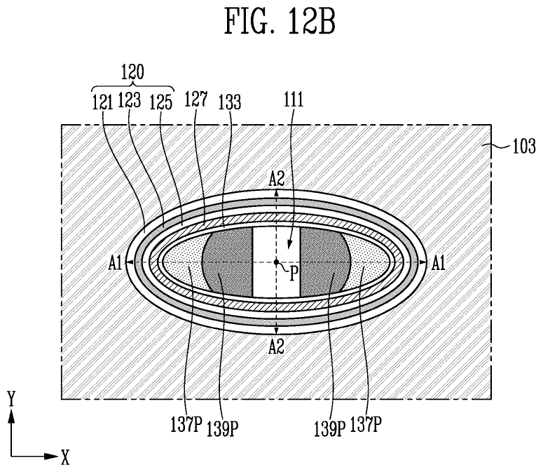

FIGS. 12A and 12B are a cross-sectional view and a plan view showing a stack, a hole, and layers disposed in the hole according to an embodiment of the present disclosure. FIG. 12B is a plan view of the stack 100 shown in FIG. 12A taken along line I-I′.

Referring to FIGS. 12A and 12B, as described with reference to FIGS. 7A and 7B, the stack 100 may be formed by alternately stacking the plurality of first material layers 101 and the plurality of second material layers 103 on a lower structure (not shown). Subsequently, as described with reference to FIGS. 7A and 7B, the hole 111 extending in the stacking direction (e.g., the Z-axis direction) penetrates the plurality of first material layers 101 and the plurality of second material layers 103. The hole 111 has the same cross-sectional shape as described with reference to FIGS. 7A and 7B in the XY plane. In an embodiment, the hole 111 may have an elliptical cross section.

Subsequently, as described with reference to FIGS. 7A and 7B, the blocking insulating layer 121, the data storage layer 123, and the tunnel insulating layer 125 of the memory layer 120, the channel layer 127, and the buffer oxide layer 133 may be sequentially formed in the hole 111.

Subsequently, a seed barrier layer may be formed on the surface of the buffer oxide layer 133. The seed barrier layer may have an etching selectivity with respect to the buffer oxide layer 133. In an embodiment, the seed barrier layer may include silicon. As described with reference to FIGS. 7A and 7B, the thickness of the seed barrier layer may be greater on the first axis A1 than on the second axis A2.

The seed barrier layer is then partitioned into a plurality of seed barrier patterns 137P using the processes as described with reference to FIGS. 8A and 8B or the processes as described with reference to FIG. 11. Subsequently, as described with reference to FIG. 9A, a plurality of growth barrier patterns 139P may be grown from a plurality of inner walls of the plurality of seed barrier patterns 137P. A plurality of regions of the buffer oxide layer 133 are exposed between the plurality of growth barrier patterns 139P.

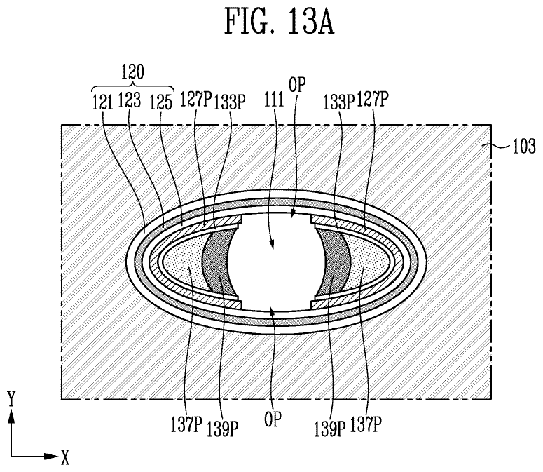

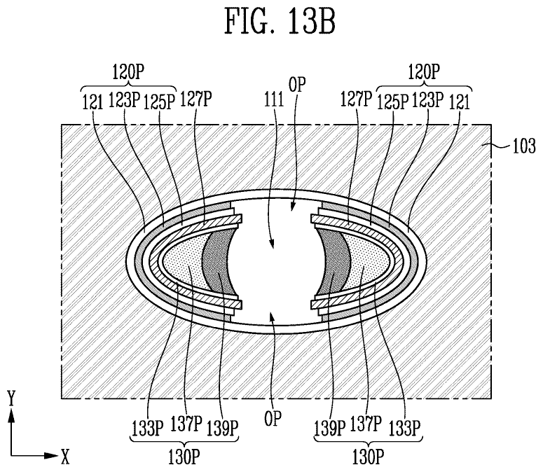

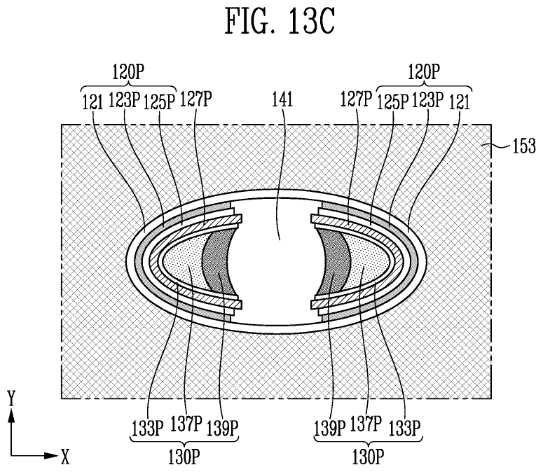

FIGS. 13A to 13C are plan views illustrating channel portions, memory portions, and a conductive layer according to an embodiment of the present disclosure.

Referring to FIG. 13A, the buffer oxide layer 133 shown in FIG. 12B may be partitioned into a plurality of buffer patterns 133P by removing the exposed regions of the buffer oxide layer 135 shown in FIG. 13B. Each buffer pattern 133P is protected by the seed barrier pattern 137P and the growth barrier pattern 139P.

Subsequently, a plurality of etching targets of the channel layer 127 as shown in FIG. 12B are removed. The plurality of etching targets are partial regions of the channel layer exposed between the plurality of buffer patterns 133P. When growth barrier pattern 139P includes silicon, a portion of the growth barrier pattern 139P may be removed when the plurality of etching targets of the channel layer are removed

A plurality of openings OP are respectively formed in regions where the plurality of etching targets of the channel layer are removed, and the channel layer 127 as shown in FIG. 12B may be partitioned into a plurality of channel portions 127P by the plurality of openings OP penetrating through the channel layer.

Referring to FIG. 13B, a plurality of regions of the tunnel insulating layer 125 as shown in FIG. 13A and a plurality of regions in the data storage layer 123 as shown in FIG. 13A are removed through the plurality of openings OP. Thus, the memory layer 120 as shown in FIG. 13A may be divided into a plurality of memory portions 120P. The plurality of memory portions 120P include a plurality of portions 125P of the tunnel insulating layer and a plurality of portions 123P of the data storage layer. The blocking insulating layer 121 may be continuous in the XY plane to surround the plurality of portions 123P of the data storage layer.

Referring to FIG. 13C, an isolation structure 141 may be formed by filling the opening OP and the hole 111 shown in FIG. 13B with an insulating material. The isolation structure 141 extends spaces between the plurality of portions 125P of the tunnel insulating layer and spaces between the plurality of portions 123P of the data storage layer.

Subsequently, by performing the processes as described with reference to FIGS. 10A and 10B, a gate stack including a conductive layer 153 may be formed.

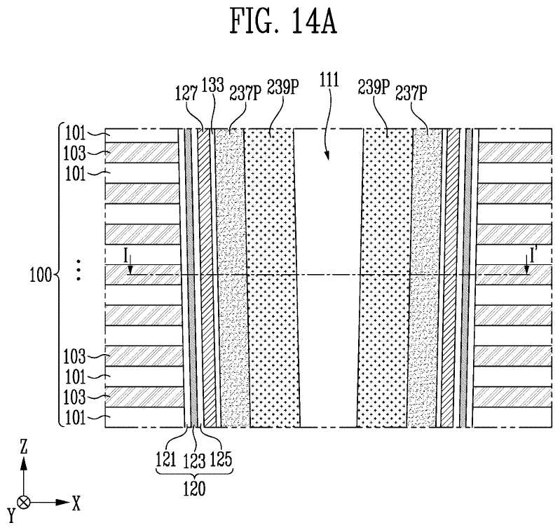

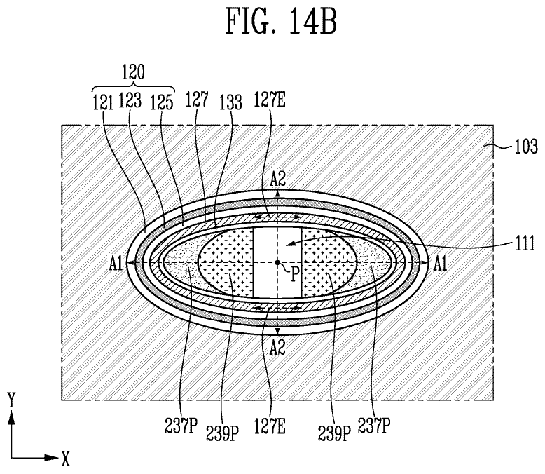

FIGS. 14A and 14B are a cross-sectional view and a plan view showing a stack, a hole, and layers disposed in the hole according to an embodiment of the present disclosure. FIG. 14B is a plan view of the stack 100 shown in FIG. 14A taken along line I-I′.

Referring to FIGS. 14A and 14B, as described with reference to FIGS. 7A and 7B, the stack 100 may be formed by alternately stacking the plurality of first material layers 101 and the plurality of second material layers 103 on a lower structure (not shown). Subsequently, as described with reference to FIGS. 7A and 7B, the hole 111 extending in the stacking direction (e.g., the Z-axis direction) penetrates the plurality of first material layers 101 and the plurality of second material layers 103. The hole 111 has the same cross-sectional shape as described with reference to FIGS. 7A and 7B in the XY plane. In an embodiment, the hole 111 may have an elliptical cross section.

Subsequently, as described with reference to FIGS. 7A and 7B, the blocking insulating layer 121, the data storage layer 123, and the tunnel insulating layer 125 of the memory layer 120, the channel layer 127, and the buffer oxide layer 133 may be sequentially formed in the hole 111.

Subsequently, a seed barrier layer may be formed on the surface of the buffer oxide layer 133. The seed barrier layer may have an etching selectivity with respect to the buffer oxide layer 133. In an embodiment, the seed barrier layer may include silicon nitride. As described with reference to FIGS. 7A and 7B, the thickness of the seed barrier layer may be greater on the first axis A1 than on the second axis A2.

The seed barrier layer is then partitioned into a plurality of seed barrier patterns 237P using the processes as described with reference to FIGS. 8A and 8B or the processes as described with reference to FIG. 11. Subsequently, a plurality of growth barrier patterns 239P are selectively grown from a plurality of inner walls of the plurality of seed barrier patterns 237P toward the center point P of the hole 111.

In an embodiment, the growth barrier pattern 239P including silicon oxy-carbide (SiOC) may be selectively grown from the seed barrier pattern 237P including silicon nitride by an AS-ALD method. The seed barrier pattern 237P grown by the AS-ALD method has a greater thickness uniformity than the seed barrier pattern formed by the deposition method. The growth barrier pattern 238P grown using the AS-ALD method may compensate for the thickness of the seed barrier pattern 237P in the direction of the first axis A1, and the growth thickness of the growth barrier pattern 238P may be controlled so that the growth barrier pattern 238P may be spaced apart from the second axis A2.

A plurality of etching targets 127E of the channel layer 127 crossing the plurality of second axes A2 are opened between the plurality of growth barrier patterns 239P. The area of the etching target 127E may be controlled according to the growth thickness of the growth barrier pattern 239P.

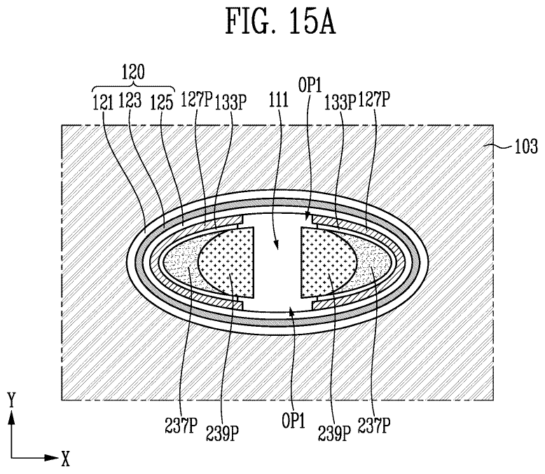

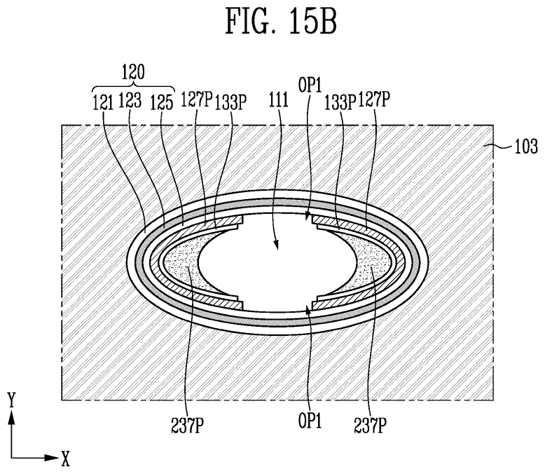

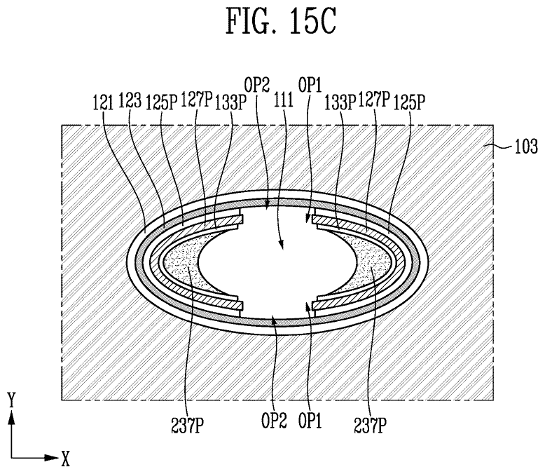

FIGS. 15A to 15C are plan views showing channel portions and openings according to an embodiment of the present disclosure.

Referring to FIG. 15A, the buffer oxide layer 133 as shown in FIG. 14B may be partitioned into the plurality of buffer patterns 133P by removing the plurality of exposed regions of the buffer oxide layer 135 shown in FIG. 15B. Each buffer pattern 133P is protected by the seed barrier pattern 237P and the growth barrier pattern 239P corresponding to the buffer pattern 133P.

Subsequently, the plurality of etching targets 127E of the channel layer 127 as shown in FIG. 14B are removed. A plurality of first openings OP1 are respectively formed in regions where the plurality of etching targets of the channel layer are removed, and the channel layer 127 as shown in FIG. 14B may be partitioned into the plurality of channel portions 127P by the plurality of first openings OP1 penetrating through the channel layer. Each buffer pattern 133P is protected by the seed barrier pattern 237P and the growth barrier pattern 239P corresponding thereto.

Referring to FIG. 15B, the plurality of growth barrier patterns 239P as shown in FIG. 15A may be selectively removed. As a result, the plurality of seed barrier patterns 237P may be opened.

Referring to FIG. 15C, a plurality of second openings OP2 may be formed by etching the tunnel insulating layer 125 as shown in FIG. 15B through the plurality of first openings OP1. The plurality of second openings OP2 may pass through the tunnel insulating layer 125 as shown in FIG. 15B and divide the tunnel insulating layer into the plurality of portions 125P. The plurality of buffer patterns 133P are protected by the plurality of seed barrier patterns 237P when the plurality of second openings OP2 are formed.

Subsequently, by etching the data storage layer 123 through the plurality of second openings OP2, the data storage layer 123 may be partitioned into the plurality of portions 123P of the data storage layer as shown in FIG. 9F. During the etching of the data storage layer 123, the plurality of seed barrier patterns 237P may be removed to expose the buffer patterns 133P as shown in FIG. 9F.

Subsequently, the processes as described with reference to FIGS. 10A and 10B may be performed.

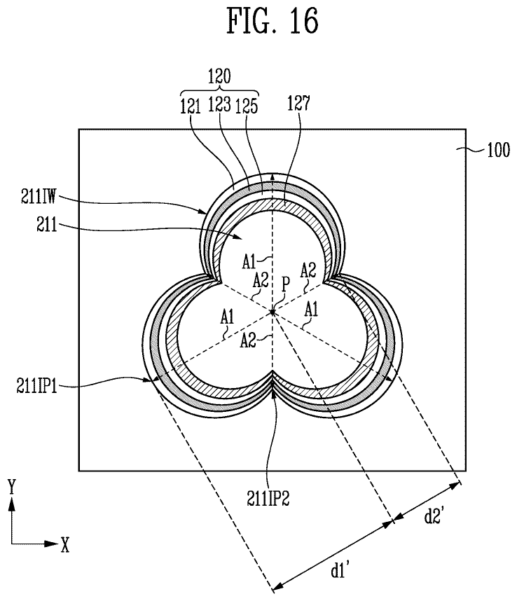

FIG. 16 is a plan view showing a stack, a hole, and layers disposed in the hole according to an embodiment of the present disclosure.

Referring to FIG. 16, the stack 100 may be penetrated by a hole 211. The stack 100 may include the plurality of first material layers 101 and the plurality of second material layers 103 as shown in FIGS. 7A and 7B.

The shape of the cross section of the hole 211 is formed on an inner wall 211IW of the hole 211 in the XY plane. In the XY plane, the inner wall 211IW is spaced apart from the center point P of the hole 211 and crosses a plurality of first axes A1 and a plurality of second axes A2. The plurality of first axes A1 and the plurality of second axes A2 extend radially from the center point P and are alternately arranged clockwise.

In the XY plane, the inner wall 211IW includes a plurality of convex portions and a plurality of concave portions. The plurality of convex portions intersect the plurality of first axes A1, respectively. The plurality of concave portions intersect the plurality of second axes A2, respectively. The vertex of each convex portion is located at a first intersection point 211PI1 between the first axis A1 and the inner wall 211IW, and the inner wall 211IW extends to be bent clockwise and counterclockwise from the first intersection point 211PI1. Each concave portion is located at a second intersection 211PI2 between the second axis A2 and the inner wall 211IW. A distance d1′ between the center point P and the first intersection 211PI1 is greater than a distance d2′ between the center point P and the second intersection 211PI2. In an embodiment, the hole 211 in the XY plane may have a substantially clover shape.

Subsequently, subsequent processes of the above-described embodiments, such as a process of forming the blocking insulating layer 121, the data storage layer 123, and the tunnel insulating layer 125 of the memory layer 120 in the hole 211, a process of forming the channel layer 127 on the inner wall of the memory layer 120, and the like, may be performed.

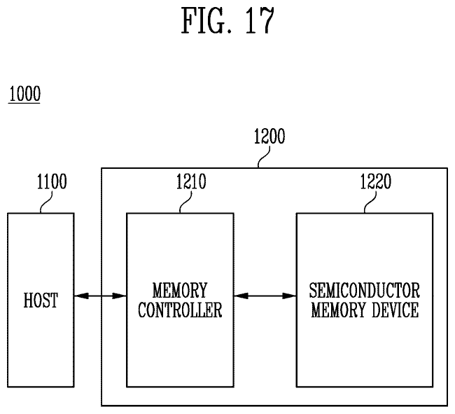

FIG. 17 is a block diagram illustrating an electronic system 1000 according to an embodiment of the present disclosure.

Referring to FIG. 17, the electronic system 1000 may include a computing system, a medical device, a communication device, a wearable device, or a memory system. The electronic system 1000 may include a host 1100 and a storage device 1200.

The host 1100 may store data in the storage device 1200, or may read the stored data from the storage device 1200 on the basis of an interface. The interface may include one or more of a Double Data Rate (DDR) interface, a Universal Serial Bus (USB) interface, a multimedia card (MMC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interface, a small computer system interface (SCSI), an enhanced small disk interface (ESDI), an Integrated Drive Electronics interface (IDE), a Firewire interface, a Universal Flash Storage (UFS) interface, and a Nonvolatile Memory express (NVMe) interface.

The storage device 1200 may include a memory controller 1210 and a semiconductor memory device 1220. According to an embodiment, the storage device 1200 may be a solid state drive (SSD), a universal serial bus (USB) memory, or the like.

The memory controller 1210 may store data in the semiconductor memory device 1220, or may read data stored in the semiconductor memory device 1220 in response to control of the host 1100.

The semiconductor memory device 1220 may include a single memory chip or a plurality of memory chips. The semiconductor memory device 1220 may store data or output stored data in response to control of the memory controller 1210.

The semiconductor memory device 1220 may be a non-volatile memory device. The semiconductor memory device 1220 may include a cell pillar structure in which an external surface is surrounded by a conductive layer. The external surface of the cell pillar structure may be arranged at difference distances from a center point on a plurality of first axes and a plurality of second axes extending radially from the center point. The cell pillar structure includes a plurality of channel portions and an isolation structure extending between the plurality of channel portions from the center point.

According to an embodiment of the present disclosure, a channel layer may extends on an inner wall of a hole formed in a stack, and the channel layer may be separated into a plurality of channel portions by partially etching the channel layer. Accordingly, in an embodiment, because a plurality of channel portions of a plurality of memory cell strings are be disposed in one hole, a degree of integration of the memory cell strings may be improved.

According to an embodiment of the present disclosure, an area of an etched region of a channel layer may be controlled by a growth barrier pattern grown from a seed barrier pattern. Accordingly, in an embodiment because division of each of the plurality of channel portions may be performed to secure a channel current, the operation reliability of the memory cell string may be improved.

What is claimed is:

1. A semiconductor memory device, comprising:
a cell pillar structure including an external surface crossing a plurality of first axes and a plurality of second axes, the plurality of first axes and the plurality of second axes radially extending from a center point in a first plane, the plurality of first axes alternately arranged in a clockwise direction with the plurality of second axes, the external surface of the cell pillar structure spaced apart from the center point, the cell pillar structure extending in a stacking direction crossing the first plane; and
a plurality of conductive layers spaced apart from each other in the stacking direction and surrounding the external surface of the cell pillar structure,
wherein the cell pillar structure includes:
a plurality of channel portions crossing the plurality of first axes, respectively, each of the plurality of channel portions including a radius of curvature defined between the center point and a vertex crossing a corresponding first axis among the plurality of first axes;
a plurality of memory portions disposed between each of the plurality of conductive layers and the plurality of channel portions; and
an isolation structure disposed between the plurality of channel portions and extending toward the center point,
wherein each of the plurality of channel portions includes an end disposed at a first distance of 30% to 80% with respect to the radius of curvature from the vertex in an extending direction of the corresponding first axis.

2. The semiconductor memory device of claim 1, wherein the external surface of the cell pillar structure includes a plurality of convex portions crossing the plurality of first axes, respectively.

3. The semiconductor memory device of claim 1, wherein in the first plane, the cell pillar structure has substantially an elliptical shape.

4. The semiconductor memory device of claim 1, wherein the external surface of the cell pillar structure includes a plurality of concave portions crossing the plurality of second axes, respectively.

5. The semiconductor memory device of claim 1,
wherein the external surface of the cell pillar structure is disposed at a second distance from the center point in the extending direction of each of the plurality of first axes, and is disposed at a third distance from the center point in an extending direction the plurality of second axes, and
wherein the third distance is less than the second distance.

6. The semiconductor memory device of claim 1, further comprising a buffer pattern disposed between an inner wall of each of the plurality of channel portions facing the center point and the isolation structure.

7. The semiconductor memory device of claim 6, further comprising a barrier pattern disposed between the buffer pattern and the isolation structure.

8. The semiconductor memory device of claim 7, wherein the barrier pattern includes:
a seed barrier pattern disposed between the buffer pattern and the isolation structure; and
a growth barrier pattern disposed between the seed barrier pattern and the isolation structure.

9. The semiconductor memory device of claim 1, wherein each of the plurality of memory portions includes:
a blocking insulating layer disposed between a corresponding channel portion among the plurality of channel portions and each of the plurality of conductive layers;
a data storage layer disposed between the blocking insulating layer and the corresponding channel portion; and
a tunnel insulating layer disposed between the data storage layer and the corresponding channel portion.

10. The semiconductor memory device of claim 9, wherein the isolation structure extends on the plurality of second axes from the center point to penetrate the data storage layer.

11. A method of manufacturing a semiconductor memory device, the method comprising:
forming a stack including a plurality of material layers extending in a first plane and arranged in a stacking direction crossing the first plane;
forming, by etching the stack, a hole including a first inner wall crossing a plurality of first axes and a plurality of second axes, the plurality of first axes and the plurality of second axes radially extending from a center point in the first plane and alternately arranged in a clockwise direction, the first inner wall spaced apart from the center point;
forming a channel layer extending on the first inner wall and including a second inner wall facing the center point;
forming a plurality of seed barrier patterns extending on the second inner wall and arranged alternately with the plurality of second axes in the clockwise direction;
selectively growing a plurality of growth barrier patterns from a plurality of third inner walls of the plurality of seed barrier patterns toward the center point to open a plurality of etching targets of the channel layer crossing the plurality of second axes; and
forming a plurality of openings by removing the plurality of etching targets to penetrate the channel layer.

12. The method of claim 11, wherein the first inner wall includes a plurality of convex portions crossing the plurality of first axes, respectively.

13. The method of claim 11, wherein in the first plane, a sidewall of the stack adjacent to the hole forms substantially an elliptical shape.

14. The method of claim 11, wherein the first inner wall includes a plurality of concave portions crossing the plurality of second axes, respectively.

15. The method of claim 11, wherein an intersection portion between each of the plurality of first axes and the first inner wall is disposed farther from the center point than an intersection portion between each the plurality of second axes and the first inner wall.

16. The method of claim 11, further comprising:
forming a memory layer extending on the first inner wall before the channel layer is formed; and
etching a plurality of regions of the memory layer through the plurality of openings.

17. The method of claim 11, wherein each of the plurality of seed barrier patterns and the plurality of growth barrier patterns includes silicon.

18. The method of claim 11, before the forming of the plurality of seed barrier patterns, further comprising:
forming a buffer oxide layer on the second inner wall; and
forming a buffer nitride layer on a surface of the buffer oxide layer, and
before the forming of the plurality of openings, further comprising:
removing a plurality of regions of the buffer nitride layer exposed between the plurality of growth barrier patterns to expose a plurality of regions of the buffer oxide layer;
removing the plurality of growth barrier patterns and the plurality of seed barrier patterns; and
removing the plurality of exposed regions of the buffer oxide layer.

19. The method of claim 11, further comprising:
forming a buffer oxide layer on the second inner wall before the forming of the plurality of seed barrier patterns;
removing a plurality of regions of the buffer oxide layer exposed between the plurality of growth barrier patterns before the forming of the plurality of openings; and
forming an isolation structure to fill a space between the plurality of growth barrier patterns and the plurality of openings.

20. The method of claim 11, further comprising:
forming a buffer oxide layer on the second inner wall before the forming of the plurality of seed barrier patterns; and
removing a plurality of regions of the buffer oxide layer exposed between the plurality of growth barrier patterns before the forming of the plurality of openings; and
removing the plurality of growth barrier patterns and the plurality of seed barrier patterns after the forming of the plurality of openings.

21. The method of claim 11,
wherein each of the plurality of seed barrier patterns includes silicon nitride, and
wherein each of the plurality of growth barrier patterns includes silicon oxy-carbide (SiOC).
